(19) United States
(12) Patent Application Publication
(10) Pub. No.: US 2010/0102872 A1
(43) Pub. Date: Apr. 29, 2010

(54) Dynamic Substrate Bias for PMOS Transistors to Alleviate NBTI Degradation

(75) Inventors: Wei-Hao Wu, Hsinchu City (TW); Anthony Oates, Hsinchu (TW)

Correspondence Address: K&L Gates LLP;IP Docketing, 630 Hansen Way, Palo Alto, CA, 94304, US

(73) Assignee: Taiwan Semiconductor Manufacturing Co., Ltd.

(21) Appl. No.: 12/260,982

(22) Filed: Oct. 29, 2008

(51) Int. Cl. G11C 5/14; G05F 3/02

(52) U.S. Cl. 327/534

(57) ABSTRACT

This invention discloses a system and method for suppressing negative bias temperature instability in PMOS transistors, the system comprises a PMOS transistor having a source connected to a power supply, and a voltage control circuitry configured to output a first and a second voltage level, the first and second voltage levels being different from each other, the first voltage level is lower than the power supply voltage, the second voltage level is equal to or higher than the power supply voltage, wherein when the PMOS transistor is turned on, the first voltage level is applied to a substrate of the PMOS transistor, and when the PMOS transistor is turned off, the second voltage level is applied to the substrate of the PMOS transistor.

### BACKGROUND

The present invention relates generally to integrated circuit (IC) design, and, more particularly, to enhancing performance and endurance of P-type metal-oxide-semiconductor (PMOS) transistors by using dynamic substrate bias therein.

Negative bias temperature instability (NBTI) is a significant reliability concern for submicron CMOS technologies, particularly to the PMOS transistors therein. It is widely believed that NBTI degradation is due to generation of interface traps, which are unsaturated silicon dangling bonds. One of the most successful models that have been able to explain NBTI phenomenon is the reaction diffusion model. This model proposes that the generation of interface traps is because of a hole induced electrochemical reaction at the Si—SiO2 interface. In the initial times the degradation is reaction rate controlled, however, with time the phenomenon becomes diffusion limited. Alternatively, it is believed that NBTI is due to a hole-trapping mechanism, whereby a hole gets trapped in a trap state, causing a shift in the threshold voltage.

NBTI has always been associated with the CMOS development, but it was not considered of great importance because of the low electric fields in operation. However, technology scaling has resulted in the convergence of several factors, which have together made NBTI the most critical reliability concern for deep submicron transistors. These trends include the introduction of nitrided oxides (required to reduce boron penetration in p⁺ poly-pMOSFETs), as well as the increase in gate oxide fields and operating temperature with technology scaling.

As such, what is desired is a system and method that can alleviate NBTI in PMOS transistors while improving circuit performance.

### SUMMARY

This invention discloses a system and method for suppressing negative bias temperature instability (NBTI) in PMOS transistors, the system comprises a PMOS transistor having a source connected to a power supply, and a voltage control circuitry configured to output a first and a second voltage level, the first and second voltage levels being different from each other, the first voltage level is lower than the power supply voltage, the second voltage level is equal to or higher than the power supply voltage, wherein when the PMOS transistor is turned on, the first voltage level is applied to a substrate of the PMOS transistor, and when the PMOS transistor is turned off, the second voltage level is applied to the substrate of the PMOS transistor.

The construction and method of operation of the invention, however, together with additional objectives and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings, wherein like reference numbers (if they occur in more than one view) designate the same elements. The invention may be better understood by reference to one or more of these drawings in combination with the description presented herein. It should be noted that the features illustrated in the drawings are not necessarily drawn to scale.

FIG. 1 is a schematic diagram illustrating a CMOS inverter with conventional substrate connections.

FIG. 2 is a schematic diagram illustrating a CMOS inverter with a power control circuitry for supplying substrate bias for the PMOS transistor according to one embodiment of the present invention.

FIG. 3 is a plot from empirical data illustrating a stress induced degradation of a PMOS transistor.

### DESCRIPTION

The present invention discloses a system and method for dynamically biasing the substrate of PMOS transistors so that the degradation due to negative bias temperature instability (NBTI) is alleviated while the performance of the circuit that includes the PMOS transistors is improved.

According to a NBTI reaction-diffusion model, the interface trap density (ΔNᵢₜ) is expressed as:

ΔNᵢₜ(t)˜Nₒ^{2/3}exp(2γEₒₓ/3)[D₀exp(−E_{D}/kT)]^{1/6}t^{1/6} Eq. 1

where Nₒ is the maximum available Si—H density, D₀ is the diffusion coefficient, Eₒₓ is the oxide carrier-induced electric field, E_{D} is the activation energy of neutral H₂ diffusion, and T is the temperature.

The oxide carrier-induced electric field Eₒₓ is calculated as:

$${E}_{ox} = \frac{{Q}_{inv}}{{ɛ}_{Si} {A}_{G}} \sim {Q}_{inv} \qquad Eq . 2$$

where Qᵢₙᵥ is the inversion charge, ε_{Si} is the silicon permittivity, A_{G} is the gate oxide area. According to Eqs. 1 and 2, the interface trap density (ΔNᵢₜ), i.e., NBTI, can be reduced by decreasing the inversion charge Qᵢₙᵥ.

Also well known in the art is that the NBTI induces a transistor's threshold voltage (Vt) shift, because the NBTI cause driving current degradation. The Vt shift can be expressed as:

$$Δ Vt \sim ( Vg - Vt 0 ) * \frac{Δ Idsat}{Idsat 0} \qquad Eq . 3$$

where Vg is the gate voltage, and Vt0 is the initial device threshold voltage. Therefore, if the Vt shift is constant, the driving current degradation percentage (ΔIdsat/Idsat0) would be inversely proportional to the (Vg−Vt0) term, where Vg is constant and Vt0 could be adjusted by applying different substrate bias. According to Eq. 3, when a reverse substrate bias is applied to reduce the sub-threshold leakage, a potential problem of shorter NBTI reliability lifetime or faster PMOS device performance degradation rate may rise.

The present invention mainly concerns about the Idsat degradation, instead of the device Vt shift. Because under circuit operation conditions like ring oscillator, the oscillation frequency is directly proportional to the Idsat, not the device Vt. That is why our idea may help a lot in suppressing the NBTI reliability problem in an effective way but without changing the most critical gate oxide recipe of ultra-thin SiON.

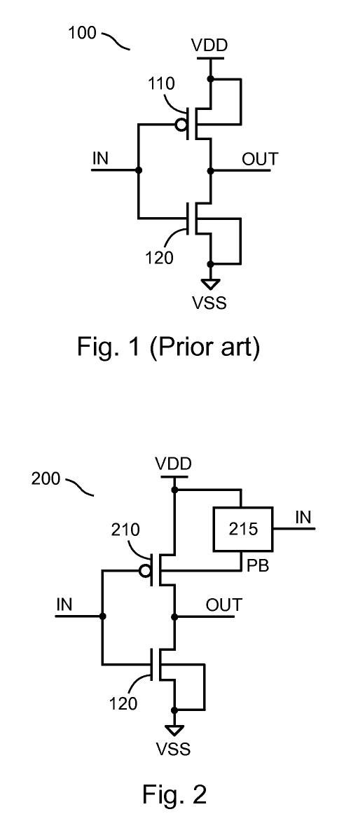

FIG. 1 is a schematic diagram illustrating a CMOS inverter 100 with conventional substrate connections. A PMOS transistor 110 in the CMOS inverter 100 has a source, drain, gate and substrate connected to a power supply VDD, an output terminal OUT, an input terminal IN and the VDD, respectively. Having the substrate of the PMOS transistor 110 connected to the VDD is conventional. When the input signal IN is at the VDD, or a logic HIGH, the PMOS transistor 110 is turned off. When the input signal IN is at the VSS, or a logic LOW, the PMOS transistor 110 is turned on. Symmetrically, a NMOS transistor 120 in the CMOS inverter 100 has a source, drain, gate and substrate connected to a ground VSS, the output terminal OUT, the input terminal IN and the VSS, respectively. The substrates of the PMOS transistor 110 and NMOS transistor 120 are formed in different wells.

FIG. 2 is a schematic diagram illustrating a CMOS inverter 200 with a power control circuitry 215 for supplying a substrate bias for the PMOS transistor 210 according to one embodiment of the present invention. A source, drain and gate of the PMOS transistor 210 is still connected to the VDD, the output terminal OUT and the input terminal IN, respectively. But the substrate of the PMOS transistor 210 is connected to an output terminal PB of the power control circuitry 215, which takes in the VDD and produces a varied bias voltage V_PB at the output terminal PB in synchronization with the input signal IN. When the PMOS transistor 210 is to be turned on, i.e., the input signal IN is at the VSS, if the substrate bias V_PB is less than the conventional VDD, than an electrical field of the gate oxide, as well as Idsat degradation of the PMOS transistor 210 is reduced, so that the NBTI therein is alleviated. On the other hand, lowering the V_PB lowers the threshold voltage of the PMOS transistor 210, which results in a higher conduction current and thereby higher performance. When the PMOS transistor 210 is to be turned off, i.e., the input signal IN is at the VDD, the substrate bias V_PB is switched back to the VDD, or even better to a voltage higher than the VDD, which raises the threshold voltage of the PMOS transistor 210, thus reduces subthreshold leakage thereof. Therefore, dynamically controlling the substrate bias of the PMOS transistor 210 in aforementioned time instances can reduce NBTI, increase conduction current and reduce subthreshold leakage all on the same PMOS transistor 210.

Referring again to FIG. 2, the power control circuitry 215 takes in the input signal IN for producing the synchronized bias voltage V_PB. However, switching the bias voltage V_PB may encounter serious delays due to the large substrate capacitance. This may limit the present invention to low switching frequency applications, such as applying different substrate biases to a specific circuit block in different operation modes: forward substrate bias in a normal operation mode, and reverse substrate bias in an idle or power saving mode. However, a skilled in the art would recognize that power control circuitry may use some other signals for the synchronization purpose. The V_PB may vary between one half of the VDD to minus one half of the VDD. The upper and lower limits of V_PB are to prevent the turn-on of parasitic PNP bipolar BJT. Circuit design trade-offs among performance, power dissipation, and long-term reliability are also consideration for the range of the V_PB variations. It may also provide many different approaches for the circuit designer to meet different circuit specs or requirements. A skilled in the art would have no difficulty to device such voltage control circuitry 215. Although the inverter 200 is used to describe the concept of the present invention, a skill in the art would appreciate that varying substrate bias voltage during different operation mode, i.e., on or off, may be applied to PMOS transistors in other circuits, such as NAND gate, etc.

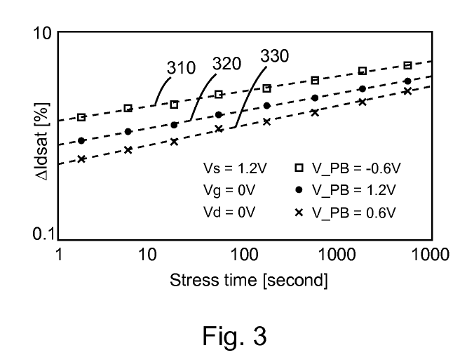

FIG. 3 is a plot from empirical data illustrating a stress induced degradation of a PMOS transistor. The horizontal coordinate is a stress time in seconds on a logarithmic scale. The vertical coordinate is a percentage change of the PMOS transistor's source-drain saturation current (ΔIdsat), which can be expressed as:

ΔIdsat=[ΔIdsat0−ΔIdsat1]/ΔIdsat0 Eg. 3

where, ΔIdsat 0 is an initial source-drain saturation current and ΔIdsat 1 is an after-stress source-drain saturation current. The source-drain saturation current decrease is a result of NBTI degradation over a period of time.

Referring again to FIG. 3, a source, drain and gate of the PMOS transistor is applied a constant 1.2V, 0V and 0V, respectively, during the stress. A substrate of the PMOS transistor is applied different bias voltages V_PB during different stresses. The V_PB is separately set at −1.8V, 1.2V or 0.6V. As shown in FIG. 3, an extrapolated line 310 represents a stress result of V_PB=−0.6V. In this case the percentage change of the source-drain saturation current (ΔIdsat) is the highest. An extrapolated line 320 represents a stress result of V_PB=1.2V. In this case the percentage change of the source-drain saturation current (ΔIdsat) is in the middle. An extrapolated line 330 represents a stress result of V_PB=0.6V. Therefore, empirically, biasing the PMOS transistor's substrate to reduce the gate-substrate voltage and reducing Idsat degradation can alleviate the NBTI degradation effect on the PMOS transistor.

Although only PMOS transistor is used to illustrate the effect of substrate bias, as NMOS transistor is symmetric in characteristics to the PMOS transistor, a skilled artisan would appreciate the present invention can be applied to the NMOS transistor circuits as well to suppress the NBTI effect. Due to reduced gate oxide voltage, hot-carrier-injection (HCI) can apparently be reduced.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

1. An integrated circuit comprising:
a PMOS transistor having a gate coupled to an input signal and a source connected to a power supply voltage; and
a voltage control circuitry coupled to the power supply and configured to output a first voltage level and a second voltage level in synchronization wit the input signal, the first and second voltage levels being different from each other, the first voltage level is lower than the power supply voltage,
wherein when the PMOS transistor is turned on, the first voltage level is applied to a substrate of the PMOS transistor, and when the PMOS transistor is turned oft the second voltage level is applied to the substrate of the PMOS transistor, and wherein the second voltage level is higher than the power supply voltage.

2-4. (canceled)

5. The integrated circuit of claim 1, wherein the first voltage equals to one half of the power supply voltage.

6. The integrated circuit of claim 1, wherein the second voltage equals to one and a half of the power supply voltage.

7. The integrated circuit of claim 1, wherein the substrate of the PMOS transistor is an Nwell.

8. The integrated circuit of claim 7, wherein the Nwell is formed in a P-type silicone wafer.

9. An integrated circuit comprising:
a PMOS transistor having a gate coupled to an input signal and a source connected to a power supply voltage; and
a voltage control circuitry coupled to the power supply and configured to output a first voltage level and a second voltage level in synchronization with the input signal, the first and second voltage levels being different from each other, the first voltage level is lower than the power supply voltage, the second voltage level is equal to higher than the power supply voltage to reduce subthreshold leakage of the PMOS transistor,
wherein when the PMOS transistor is turned on, the first voltage level is applied to a substrate of the PMOS transistor, and when the PMOS transistor is turned oft the second voltage level is applied to the substrate of the PMOS transistor.

10-11. (canceled)

12. The integrated circuit of claim 9, wherein the first voltage equals to one half of the power supply voltage.

13. The integrated circuit of claim 9, wherein the second voltage equals to one and a half of the power supply voltage.

14. The integrated circuit of claim 9, wherein the substrate of the PMOS transistor is an Nwell.

15. A method for suppressing negative bias temperature instability (NBTI) in a PMOS transistor, the method comprise:
providing a power supply and an input signal to a source and a gate of the PMOS transistor, respectively;
biasing a substrate of the PMOS transistor to a first voltage level when the PMOS transistor being turned on, the first voltage level being lower than a power supply voltage level; and
biasing the substrate of the PMOS transistor to a second voltage level when the PMOS transistor being turned off, the second voltage level being different from the first voltage level, wherein the first and second voltage levels are produced by a voltage control circuitry coupled to the power supply in synchronization with the input signal, and the second voltage level is higher than the power supply voltage level.

16-17. (canceled)

18. The method of claim 15, wherein the first voltage equals to one half of the power supply voltage level.

19. The method of claim 15, wherein the second voltage equals to one and a half of the power supply voltage level.

20. The method of claim 15, wherein the substrate of the PMOS transistor is an Nwell.
